(19) United States
(12) Patent Application Publication
(10) Pub. No.: US 2008/0138746 A1
(43) Pub. Date: Jun. 12, 2008

(54) Pattern formation method using fine pattern formation material for use in semiconductor fabrication step

(76) Inventors: Takehiro Kondoh, Yokohama-shi (JP); Eishi Shiobara, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/896,870

(22) Filed: Sep. 6, 2007

(30) Foreign Application Priority Data
Sep. 8, 2006 (JP) 2006-244427

(51) Int. Cl. G03F 7/26

(52) U.S. Cl. 430/326

(57) ABSTRACT

A resist pattern is formed on the major surface of a semiconductor substrate, and coated with a water-soluble pattern formation material having thermal crosslinking properties in the presence of an acid. A crosslinking film is formed by heating in that portion of the water-soluble pattern formation material which is in contact with the resist pattern. A pattern is formed by removing a portion of the water-soluble pattern formation material except for the crosslinking film by using an aqueous alkali solution containing a surfactant.

### CROSS-REFERENCE TO RELATED APPLICATIONS

This application is based upon and claims the benefit of priority from prior Japanese Patent Application No. 2006-244427, filed Sep. 8, 2006, the entire contents of which are incorporated herein by reference.

### BACKGROUND OF THE INVENTION

1. Field of the Invention

The present invention relates to a pattern formation method using a fine pattern formation material for use in a semiconductor fabrication step and, more particularly, to a development process.

2. Description of the Related Art

Micropatterning of the semiconductor process is steadily advancing. Examples of approaches in the lithography technique are a short exposure wavelength and high numerical aperture (NA) of an exposure apparatus. However, these approaches require new installations, and this increases the cost and requires large process changes. Also, micropatterning of resist patterns by the exposure wavelength has its limit.

Accordingly, attempts have been made to reduce the cost and process changes. As an improvement in resist process, micropatterning of resist patterns by Resolution Enhancement Lithography Assisted by Chemical Shrinkage (RELACS) processing using a water-soluble fine pattern formation material has been proposed (e.g., Jpn. Pat. Appln. KOKAI Publication No. H10-73927).

In this RELACS processing, an ordinary resist pattern is first formed and then coated with a water-soluble fine pattern formation material, and a crosslinking film is formed by heating. After that, a development process is performed to remove a non-crosslinking portion.

If pure water alone is used in this development process, a development defect occurs in the film. This development defect occurring in the RELACS processing is a problem because it closes an opening in the initial resist pattern.

To suppress this development defect, a method that uses an aqueous surfactant solution in the development process has been proposed (e.g., Jpn. Pat. Appln. KOKAI Publication No. P2002-49161). However, this method also has the problem that the aqueous surfactant solution is expensive.

### BRIEF SUMMARY OF THE INVENTION

A pattern formation method according to an aspect of the present invention comprising forming a resist pattern on a major surface of a semiconductor substrate, coating the resist pattern with a water-soluble pattern formation material having thermal crosslinking properties in the presence of an acid, forming, by heating, a crosslinking film in a portion of the water-soluble pattern formation material which is in contact with the resist pattern, and removing a portion of the water-soluble pattern formation material except for the crosslinking film by using an aqueous alkali solution containing a surfactant.

### BRIEF DESCRIPTION OF THE SEVERAL VIEWS OF THE DRAWING

FIG. 1 is a sectional view showing a fabrication step of a pattern formation method according to the first and second embodiments of the present invention;

FIG. 2 is a sectional view showing a fabrication step, which follows FIG. 1, of the pattern formation method according to the first and second embodiments;

FIG. 3 is a sectional view showing a fabrication step, which follows FIG. 2, of the pattern formation method according to the first and second embodiments;

FIG. 4 is a sectional view showing a fabrication step, which follows FIG. 3, of the pattern formation method according to the first and second embodiments;

FIG. 5 is a sectional view showing a fabrication step, which follows FIG. 4, of the pattern formation method according to the first and second embodiments;

FIG. 6 is a sectional view showing a fabrication step, which follows FIG. 5, of the pattern formation method according to the first embodiment;

FIG. 7 is a photograph showing linear defects detected by using an optical defect test apparatus;

FIG. 8 is a sectional view showing a fabrication step of the conventional pattern formation method;

FIG. 9 is a sectional view showing a fabrication step, which follows FIG. 8, of the conventional pattern formation method;

FIG. 10 is a defect map when a defect test was performed during resist pattern formation before the RELACS processing;

FIG. 11 is a defect map when a defect test was performed after a development process of the first embodiment was performed in the RELACS processing;

FIG. 12 is a defect map when a defect test was performed after the conventional development process was performed in the RELACS processing; and

FIG. 13 is a sectional view showing a fabrication step, which follows FIG. 5, of the pattern formation method according to the second embodiment.

### DETAILED DESCRIPTION OF THE INVENTION

### First Embodiment

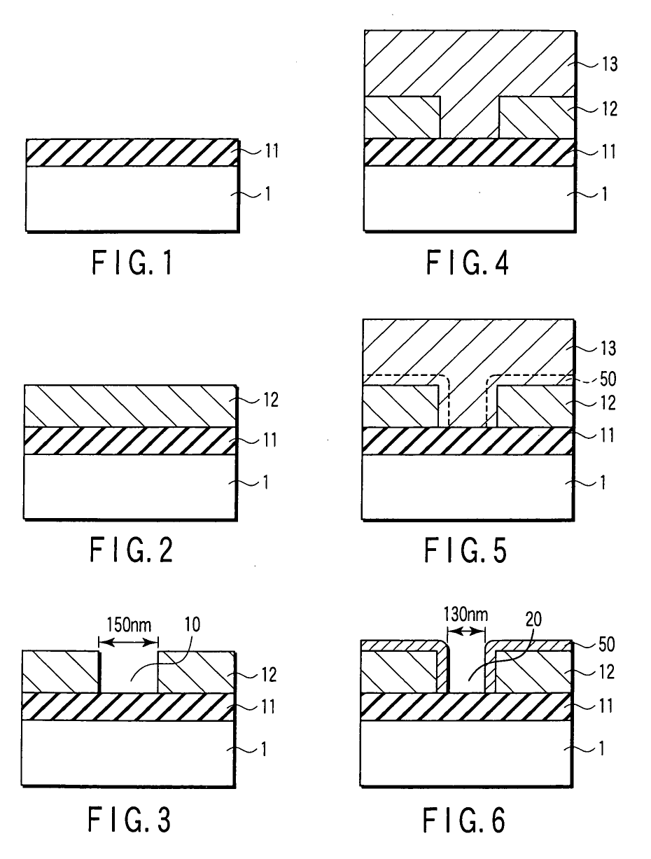

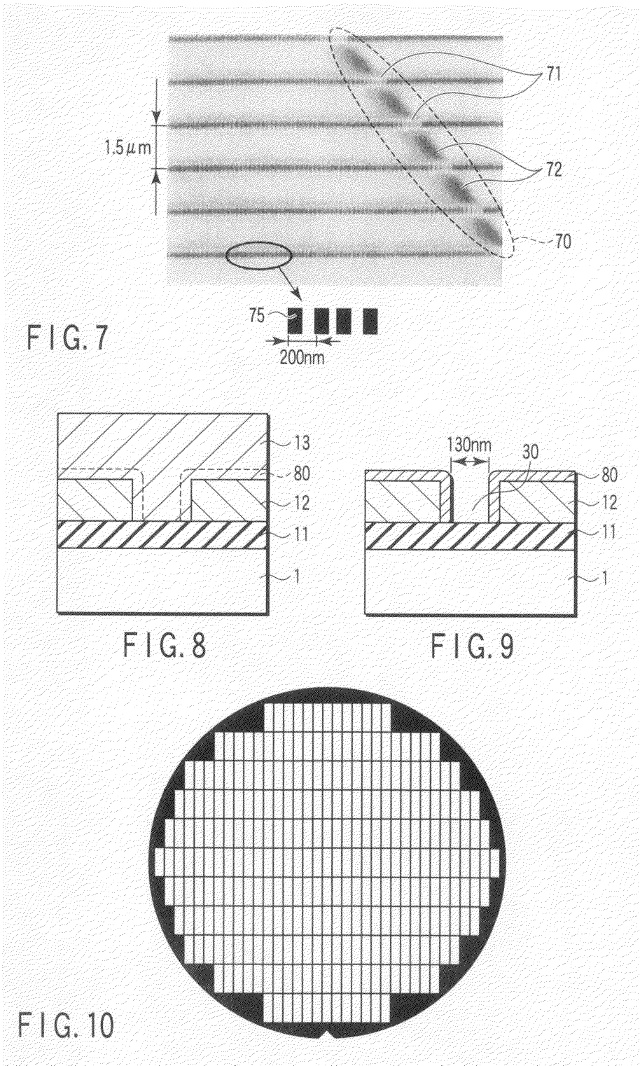

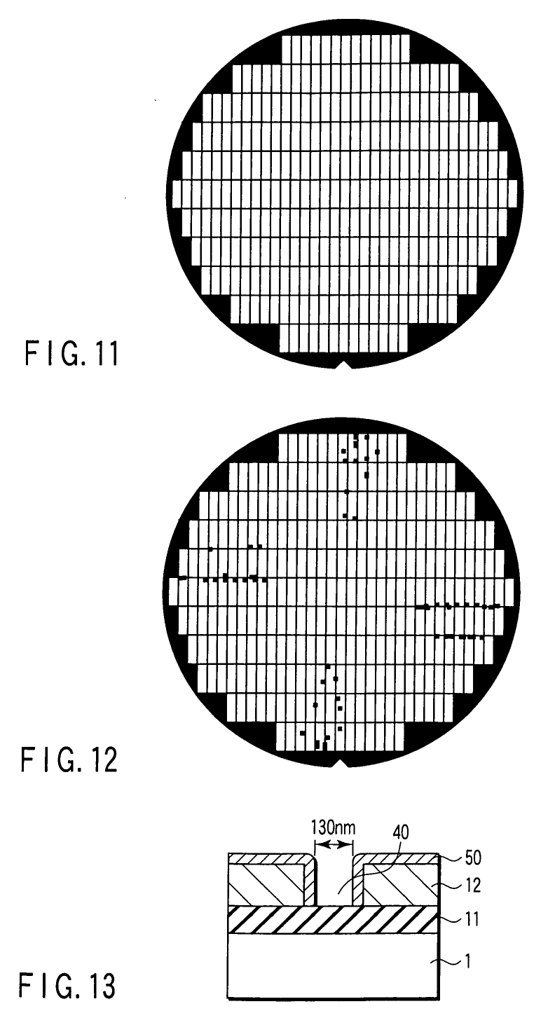

A pattern formation method according to the first embodiment of the present invention will be explained below with reference to FIGS. 1 to 6.

### [Resist Pattern Formation Before RELACS Processing]

First, as shown in FIG. 1, a semiconductor substrate 1 was coated with an ArF organic antireflection film (e.g., ARC29A manufactured by Nissan Chemical Industries) by spin coating, and baked at a temperature of 215° C. for 1 minute in order to vaporize the solvent, thereby forming an 80-nm-thick antireflection film 11.

After that, as shown in FIG. 2, the antireflection film 11 was coated with an ArF positive resist (manufactured by, e.g., JSR) by spin coating, and baking was performed at a temperature of 130° C. for 1 min, thereby forming a 400-nm-thick resist film 12.

Then, an ArF excimer laser exposure apparatus was used to expose the resist film 12 at NA=0.78 with ⅔ zonal illumination by using a halftone mask (not shown) having a transmittance of 6%. After that, baking was performed at a temperature of 100° C. for 1 min. This is post-exposure bake (PEB) that accelerates the reaction (elimination reaction) between an acid and elimination group generated by exposure in a chemical amplification type resist.

Subsequently, development was performed with an aqueous 2.38-wt % tetramethyl ammonium hydroxide (TMAH) solution, thereby forming a contact hole pattern 10 having a diameter of 150 nm as shown in FIG. 3. Note that development may also be performed by using an aqueous surfactant-containing 2.38-wt % tetramethyl ammonium hydroxide (TMAH) solution (e.g., AD-10 developer manufactured by Tama Chemicals).

### [RELACS Processing]

As shown in FIG. 4, the contact hole pattern 10 was coated with a 300-nm-thick RELACS material (e.g., R602 manufactured by AZ Electronic Materials) 13 as a water-soluble pattern formation material by spin coating.

After that, as shown in FIG. 5, baking was performed at a temperature of 155° C. for 90 seconds to form a crosslinking film 50 in that portion of the RELACS material 13 which was in contact with the resist pattern 12.

Then, a development process was performed. In this development process, rinsing was first performed for 40 seconds by using pure water, then performed for 10 seconds by using an aqueous surfactant-containing 2.38-wt % tetramethyl ammonium hydroxide (TMAH) solution (e.g., AD-10 developer manufactured by Tama Chemicals), and finally performed for 10 seconds by using pure water. As shown in FIG. 6, this development process removed a portion of the RELACS material 13 except for the crosslinking film 50, thereby forming a contact hole pattern 20.

Note that the development process described above is not limited to the above procedure as long as an aqueous surfactant-containing tetramethyl ammonium hydroxide (TMAH) solution is used, and it is not always necessary to use pure water.

Note also that using the aqueous surfactant-containing 2.38-wt % tetramethyl ammonium hydroxide (TMAH) solution to form the contact hole pattern 10 simplifies the processing because the same developer is used in the development process of the RELACS processing.

After that, spin drying was performed. When measured using a critical dimension SEM, the diameter of the contact hole pattern 20 having undergone the RELACS processing was 130 nm, i.e., shrunk by 20 nm from that of the contact hole pattern 10 (FIG. 6).

### [Defect Test]

An optical defect test apparatus was used to perform a defect test on the state shown in FIG. 3 in which the contact hole pattern 10 was formed, and the state shown in FIG. 6 in which the contact hole pattern 20 was formed. Table 1 shows the numbers of linear defects formed on the wafers in the states in which these patterns were formed.

TABLE 1

| | Number of |
|---|---|
| | linear defects |
| Before RELACS processing | 5 |
| (hole pattern 10) | |
| After RELACS processing | 5 |
| (hole pattern 20) | |

Table 1 reveals that the number of defects before the RELACS process remained unchanged after that.

An example of the counted linear defects is a linear defect 70 as shown in a photograph of FIG. 7. The linear defect 70 is a macro defect formed on an evaluation pattern obtained by juxtaposing some contact hole patterns 75, and including contact hole patterns 71 having imperfect openings and resist regions 72 whose film thickness varies.

For comparison, the conventional pattern formation method will be explained. The conventional pattern formation method was the same as this embodiment until, e.g., the step shown in FIG. 4. After that, as shown in FIG. 8, baking was performed at a temperature of 150° C. for 90 seconds to form a crosslinking film 80 in that portion of the RELACS material 13 which was in contact with the resist pattern 12. Note that the baking temperature was lower than that of this embodiment in order to reduce the thermal crosslinking amount to match the diameter of a finally formed contact hole pattern with that of this embodiment, by taking account of the difference between the pattern shrink amounts caused by the difference between a development step to be explained below and the development step of this embodiment.

After that, rinsing was performed for 60 seconds by using pure water alone in a development process. As shown in FIG. 9, this development process removed a portion of the RELACS material except for the crosslinking film 80, thereby forming a contact hole pattern 30.

After that, spin drying was performed. When measured using a critical dimension SEM, the diameter of the contact hole pattern 30 having undergone the RELACS processing was 130 nm, i.e., shrunk by 20 nm from that of the contact hole pattern 10 (FIG. 9).

An optical defect test apparatus was used to perform a defect test on the state shown in FIG. 3 in which the contact hole pattern 10 was formed, and the state shown in FIG. 9 in which the contact hole pattern 30 was formed. Table 2 shows the numbers of linear defects formed on the wafers in the states in which these patterns were formed.

TABLE 2

| | Number of |
|---|---|
| | linear defects |
| Before RELACS processing | 0 |
| (hole pattern 10) | |
| After RELACS processing | 35 |
| (hole pattern 30) | |

Table 2 reveals that the number of defects increased after the RELACS process.

The development method according to this embodiment was further compared with the conventional development method by using another evaluation pattern. The results will be described below.

An optical defect test apparatus was used to perform a defect test on three different wafers. FIGS. 10 to 12 illustrate the results as defect maps indicating the distributions of linear defects on the wafers.

FIG. 10 is a defect map when a defect test was performed during resist pattern formation before the RELACS processing. FIG. 11 is a defect map when a defect test was performed after a development process was performed by using pure water, an aqueous surfactant-containing 2.38-wt % tetramethyl ammonium hydroxide (TMAH) solution (AD-10 developer manufactured by Tama Chemicals), and pure water in this order in the RELACS processing. FIG. 12 is a defect map when a defect test was performed after a development process was performed by using pure water alone as in the conventional method in the RELACS processing.

Table 3 shows the numbers of linear defects formed on the wafers in these cases.

TABLE 3

| | Number of |
|---|---|
| | linear defects |
| Before RELACS processing | 0 |
| (FIG. 10) | |
| Pure water → aqueous TMAH | 0 |
| solution → pure water (FIG. 11) | |
| Pure water alone (FIG. 12) | 73 |

A large number of linear defects occurred in the case shown in FIG. 12 in which the development process was performed using only pure water. By contrast, no linear defects occurred in the case of this embodiment shown in FIG. 11 in which the aqueous surfactant-containing 2.38-wt % tetramethyl ammonium hydroxide (TMAH) solution (AD-10 developer manufactured by Tama Chemicals) was used.

As explained above, it was possible to prevent the occurrence of development defects as the conventional problem caused by the RELACS process, by using the aqueous surfactant-containing 2.38-wt % tetramethyl ammonium hydroxide (TMAH) solution, as an aqueous alkali solution containing a surfactant, in the development process.

This embodiment uses the existing developer that is conventionally widely used. This makes it possible to inexpensively and simply avoid the occurrence of development defects, i.e., unopened patterns.

### Second Embodiment

A pattern formation method according to the second embodiment of the present invention will be explained below with reference to FIGS. 1 to 5 and 13.

### [Resist Pattern Formation Before RELACS Processing]

Exactly the same steps as in the pattern formation method according to the first embodiment were performed.

### [RELACS Processing]

The steps were exactly the same as in the pattern formation method according to the first embodiment until the step shown in FIG. 5.

After that, a development process was performed. In this development process, rinsing was first performed for 40 seconds by using pure water, then performed for 10 seconds by using an aqueous surfactant-containing 2.38-wt % potassium hydroxide (KOH) solution, and finally performed for 10 seconds by using pure water. As shown in FIG. 13, this development process removed a portion of a RELACS material 13 except for a crosslinking film 50, thereby forming a contact hole pattern 40.

Note that the development process described above is not limited to the above procedure as long as an aqueous surfactant-containing potassium hydroxide (KOH) solution is used, and it is not always necessary to use pure water.

After that, spin drying was performed. When measured using a critical dimension SEM, the diameter of the contact hole pattern 40 having undergone the RELACS processing was 130 nm, i.e., shrunk by 20 nm from that of a contact hole pattern 10 (FIG. 13).

### [Defect Test]

An optical defect test apparatus was used to perform a defect test on the state shown in FIG. 3 in which the contact hole pattern 10 was formed, and the state shown in FIG. 13 in which the contact hole pattern 40 was formed. Table 4 shows the numbers of linear defects formed on the wafers in the states in which these patterns were formed.

TABLE 4

| | Number of |
|---|---|
| | linear defects |
| Before RELACS processing | 7 |
| (hole pattern 10) | |
| After RELACS processing | 7 |
| (hole pattern 40) | |

Table 4 reveals that the number of defects before the RELACS process remained unchanged after that.

As explained above, it was possible to prevent the occurrence of development defects, i.e., unopened patterns caused by the RELACS process, without using any expensive aqueous surfactant solution, by using an aqueous surfactant-containing 2.38-wt % potassium hydroxide (KOH) solution as an aqueous alkali solution containing a surfactant in the development process.

As described above, according to one aspect of this invention, it is possible to provide a pattern formation method using a water-soluble pattern formation material and capable of simply and inexpensively suppressing development defects.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern formation method comprising:
forming a resist pattern on a major surface of a semiconductor substrate;
coating the resist pattern with a water-soluble pattern formation material having thermal crosslinking properties in the presence of an acid;
forming, by heating, a crosslinking film in a portion of the water-soluble pattern formation material which is in contact with the resist pattern; and
removing a portion of the water-soluble pattern formation material except for the crosslinking film by using an aqueous alkali solution containing a surfactant.

2. A method according to claim 1, wherein forming the resist pattern includes:
forming an antireflection film on the major surface of the semiconductor substrate;
coating the antireflection film with an ArF positive resist;
exposing the ArF positive resist; and
developing the ArF positive resist.

3. A method according to claim 2, wherein forming the antireflection film includes coating the major surface of the semiconductor substrate with an ArF organic antireflection film, and vaporizing a solvent contained in the ArF organic antireflection film.

4. A method according to claim 2, further comprising performing baking after coating the ArF positive resist.

5. A method according to claim 2, further comprising performing post baking after exposing the ArF positive resist.

6. A method according to claim 1, wherein the water-soluble pattern formation material includes a Resolution Enhancement Lithography Assisted by Chemical Shrinkage (RELACS) material.

7. A method according to claim 1, wherein forming the crosslinking film performs baking at a temperature of preferably 50 to 200° C. for 5 to 300 seconds.

8. A method according to claim 1, wherein the removing includes a first rinsing process of performing rinsing with pure water before removing the portion except for the crosslinking film.

9. A method according to claim 8, wherein the removing comprises a second rinsing process of performing rinsing with pure water after removing the portion except for the crosslinking film.

10. A method according to claim 9, further comprising performing drying after the second rinsing process.

11. A method according to claim 1, wherein the aqueous alkali solution containing a surfactant is an aqueous solution containing tetramethyl ammonium hydroxide.

12. A method according to claim 11, wherein a concentration of the tetramethyl ammonium hydroxide in the aqueous solution is preferably 0.1 to 50 wt %.

13. A method according to claim 1, wherein the aqueous alkali solution containing a surfactant is an aqueous solution containing potassium hydroxide.

14. A method according to claim 13, wherein a concentration of the potassium hydroxide in the aqueous solution is preferably 0.1 to 50 wt %.

15. A method according to claim 1, wherein the aqueous alkali solution containing a surfactant is a developer in a case of used in case forming the resist pattern.
